(19) United States
(12) Patent Application Publication
(10) Pub. No.: US 2008/0273391 A1
(43) Pub. Date: Nov. 6, 2008

(54) Regulator Bypass Start-Up in an Integrated Circuit Device

(75) Inventors: Sean Steedman, Phoenix, AZ (US); Vivien Delport, Chandler, AZ (US); Jerrold S. Zdenek, Maricopa, AZ (US); Ruan Lourens, Volente, TX (US); Michael Charles, Gilbert, AZ (US); Joseph Julicher, Maricopa, AZ (US); Eric Schroeder, Gahanna, OH (US)

Correspondence Address: Attention of : Paul N. Katz;Baker Botts L.L.P., One Shell Plaza, 910 Louisiana Street, Houston, TX, 77002-4995, US

(73) Assignee: Microchip Technology Incorporated

(21) Appl. No.: 12/102,400

(22) Filed: Apr. 14, 2008

Related U.S. Application Data
(60) Provisional application No. 60/915,960, filed on May 4, 2007.

(51) Int. Cl. G11C 5/14; G11C 11/34

(52) U.S. Cl. 365/185.18; 365/226; 365/185.33; 365/227

(57) ABSTRACT

An internal voltage regulator in an integrated circuit device is always active upon initial start-up and/or power-on-reset operations. The internal voltage regulator protects the low voltage core logic circuits of the integrated circuit device from excessively high voltages that may be present in a particular application. In addition, nonvolatile memory may be part of and operational with the low voltage core logic circuits for storing device operating parameters. Therefore, the internal voltage regulator also protects the low voltage nonvolatile memory from excessive high voltages. Once the integrated circuit device has stabilized and all logic circuits therein are fully function, a bit(s) in the nonvolatile memory may be read to determine if the internal voltage regulator should remain active, e.g., how power operation with a high voltage source, or be placed into a bypass mode for low power operation when the integrated circuit device is powered by a low voltage.

### RELATED PATENT APPLICATION

This application claims priority to commonly owned U.S. Provisional Patent Application Ser. No. 60/915,960; filed May 4, 2007; entitled “Regulator Bypass Start-Up System, Method and Apparatus,” by Sean Steedman, Vivien Delport, Jerry Zdenek, Ruan Lourens, Michael Charles, Joseph Julicher and Eric Schroeder; which is hereby incorporated by reference herein for all purposes.

### TECHNICAL FIELD

The present disclosure relates to voltage regulators internal to integrated circuit devices, and more particularly, to a power-up reset to bypass the internal voltage regulator without subjecting the integrated circuit device low-voltage logic to dangerous over-voltage conditions.

### BACKGROUND

Currently, if a voltage regulator internal to an integrated circuit device is bypassed during start-up of the device, and the regulator is only activated after start-up is complete, the core/low-voltage logic components of the integrated circuit may be directly exposed to a potentially high supply voltage during the start-up.

### SUMMARY

Therefore there is a need to prevent low voltage logic from being exposed to potentially destructive over-voltage conditions by an internal voltage regulator being disabled (bypassed) during start-up such as a power-on-reset, and/or operation thereof.

According to teachings of this disclosure, an integrated circuit digital device, e.g. microcontroller has an on-board voltage regulator. The integrated internal voltage regulator may operate in the following two modes: (1) regulated mode and (2) unregulated mode (bypass). To determine which regulator operating mode is desired, a nonvolatile memory bit, e.g., configuration fuse(s), may be located on the regulated side of the voltage regulator. The regulator may be enabled or disabled by a configuration fuse(s), however the internal voltage regulator must follow a specific power-up procedure when the regulator is to be bypassed, e.g., when the regulator is not required for operation of the device logic. It is contemplated and within the scope of this disclosure that the configuration fuse(s) is being used as non-volatile memory and that any non-volatile memory may be used for this application, e.g., electrically erasable and programmable read only memory (EEPROM), FLASH memory, and the like, instead of or in conjunction with the configuration fuse(s).

Locating the nonvolatile memory (configuration fuse(s)) on the regulated side of the voltage regulator saves manufacturing costs and silicon die area. However, the low voltage logic must never be exposed to potential over-voltage conditions, not even during start-up. A user may thereby select to run off of the internal regulator, or to bypass the regulator (e.g., if the digital device is running from an external regulator, or from a lower supply voltage), by using just the configuration fuse(s). Since the fuse value(s) is only known once power is applied thereto, a procedure is followed in order to safely power up the integrated circuit device. The following procedure may be used: (1) Upon a power-up reset the internal regulator is by default enabled. (2) Thus during start-up the fuses, core and other low voltage components are only exposed to a regulated (low) supply voltage. (3) Once power is applied to the configuration fuses, the regulation configuration fuse is read. And (4) if the regulation configuration fuse indicates that the regulator should not be enabled it is bypassed, otherwise the regulator will stay enabled (remains functional and is not bypassed).

According to a specific example embodiment of this disclosure, an integrated circuit device having an internal voltage regulator and nonvolatile memory comprises: a voltage regulator; a power-on-reset (POR) circuit; nonvolatile memory; and low voltage core logic; wherein upon initial start-up of the integrated circuit device or a signal from the POR circuit, the voltage regulator regulates a low voltage output to the nonvolatile memory and the low voltage core logic, and upon subsequent reading of the nonvolatile memory, determines whether to remain active or go to a bypass mode in which the voltage regulator passes through a input power source voltage to its output without substantially changing the power source voltage.

According to another specific example embodiment of this disclosure, a method for controlling an internal voltage regulator of an integrated circuit device comprises the steps of: providing a voltage regulator in an integrated circuit device; enabling the voltage regulator during initial start-up of the integrated circuit device; supplying a regulated low voltage from the voltage regulator to nonvolatile memory and low voltage circuits of the integrated circuit device; and reading the nonvolatile memory for determining whether to retain the voltage regulator enabled or to disable and bypass the voltage regulator. The method further comprises the step of enabling the voltage regulator during a power-on-reset of the integrated circuit device.

### BRIEF DESCRIPTION OF THE DRAWINGS

A more complete understanding of the present disclosure may be acquired by referring to the following description taken in conjunction with the accompanying drawings wherein:

FIG. 1 illustrates a schematic block diagram of an integrated circuit device having internal voltage regulator enable/disable configuration fuse(s), according to a specific example embodiment of this disclosure; and

FIG. 2 illustrates a start-up state diagram of the integrated circuit device of FIG. 1, according to the specific example embodiment of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawing, the details of specific example embodiments are schematically illustrated. Like elements in the drawings will be represented by like numbers, and similar elements will be represented by like numbers with a different lower case letter suffix.

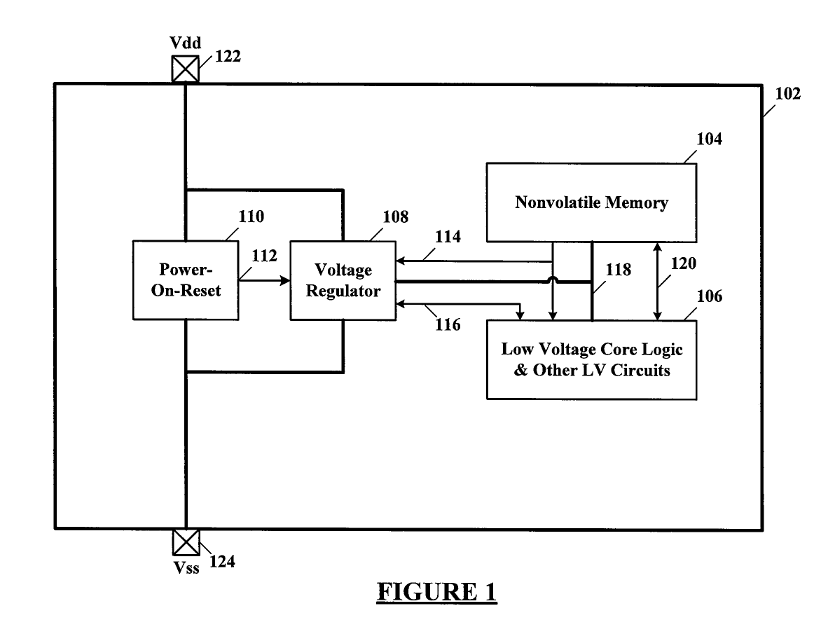

Referring to FIG. 1, depicted is a schematic block diagram of an integrated circuit device having internal voltage regulator enable/disable configuration fuse(s), according to a specific example embodiment of this disclosure. An integrated circuit device 102, e.g. microprocessor, microcontroller, digital signal processor, application specific integrated circuit (ASIC), programmable logic array (PLA), etc., comprises nonvolatile memory 104, e.g., fuses, electrically erasable read only memory (EEPROM), FLASH memory, etc.; low voltage core logic and other low voltage circuits 106, e.g., central processing unit (CPU), registers, etc., voltage regulator 108, and a power-on-reset (POR) circuit 110. The voltage regulator 108 and the POR circuit 110 are coupled to an external power source (Vdd) connection (pin) 122 and an external power common (Vss) connection (pin) 124 on an integrated circuit package (not shown) containing the integrated circuit device 102. Through these connections (pins) 122 and 124 power and common, respectively, from the power source supply operating power to the integrated circuit device 102. Low voltage as used herein may be, for example but not limited to, 3.3 volts, 1.3 volts, etc., high voltage may be, for example but not limited to, 5 volts or higher.

The nonvolatile memory 104, and the low voltage core logic and other low voltage circuits 106 receive lower voltage operating power 118 from the voltage regulator. It is important that the maximum voltage ratings of the nonvolatile memory 104, and the low voltage core logic and other low voltage circuits 106 are never exceeded. If the voltage from the power source, Vdd, (not shown) does not exceed the maximum operating voltage for nonvolatile memory 104, and the low voltage core logic and other low voltage circuits 106 and is a stable voltage source, then there is no need for voltage regulation by the voltage regulator 108. In this case, the main pass transistor(s) (not shown) of the voltage regulator 108 may be turned on hard which effectively removes the voltage regulator 108 influence on the voltage of the operating power 118 to the nonvolatile memory 104, and the low voltage core logic and other low voltage circuits 106. However, if the power source voltage at connection 122 exceeds the voltage rating of the nonvolatile memory 104, and the low voltage core logic and other low voltage circuits 106, then the voltage regulator 108 must be operative so as to limit the voltage of the operating power 118 to a safe value.

Thus, the voltage regulator must always be active upon an initial power-up or power-on-reset of the integrated circuit device 102. This may be accomplished by the POR circuit 110 signaling to the voltage regulator 108, on signal line 112, to actively regulate any incoming voltage from the connections 122 and 124 to a safe value for powering the low voltage nonvolatile memory 104, and the low voltage core logic and other low voltage circuits 106. Once the nonvolatile memory 104, and the low voltage core logic and other low voltage circuits 106 have stabilized, a bit(s) in the nonvolatile memory 104 may be read to determine whether the voltage regulator 108 needs to continue being active or can now be bypassed. Various control lines 114, 116 and 120 may be used for this purpose and other and further control and information between the various circuits of the integrated circuit device 102.

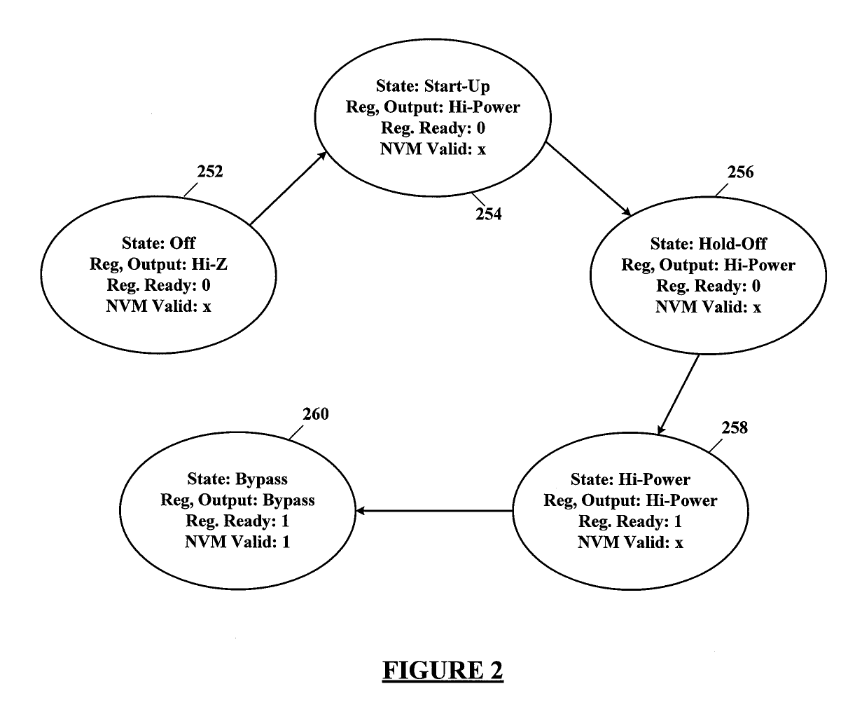

Referring to FIG. 2, depicted is a start-up state diagram of the integrated circuit device of FIG. 1, according to the specific example embodiment of this disclosure. State 252 is the initial condition at power-on reset. State 254 is after a power-on timer reset is released. State 256 starts a power stabilization timer. State 258 indicates that the voltage regulator 108 output has stabilized. And State 260 determines that the nonvolatile memory 110 bit(s), e.g., configuration fuse(s), is valid and then from the logic state of that bit(s) controls whether the voltage regulator 108 switches to a disabled (bypass) mode (deselected) or remains in the enabled mode, e.g., remains selected and operational to limit high voltage to a low voltage for the low voltage nonvolatile memory 104, and the low voltage core logic and other low voltage circuits 106.

It is contemplated and within the scope of this disclosure that the configuration fuse(s) is being used as non-volatile memory and that any non-volatile memory may be used for this application, e.g., electrically erasable and programmable read only memory (EEPROM), FLASH memory, and the like, instead of or in conjunction with configuration fuse(s).

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. An integrated circuit device having an internal voltage regulator and nonvolatile memory, said integrated circuit device comprising:
a voltage regulator;
a power-on-reset (POR) circuit;
nonvolatile memory; and
low voltage core logic;
wherein upon initial start-up of the integrated circuit device or a signal from the POR circuit, the voltage regulator regulates a low voltage output to the nonvolatile memory and the low voltage core logic, and upon subsequent reading of the nonvolatile memory, determines whether to remain active or go to a bypass mode in which the voltage regulator passes through a input power source voltage to its output without substantially changing the power source voltage.

2. The integrated circuit device according to claim 1, wherein the low voltage is a first voltage.

3. The integrated circuit device according to claim 2, wherein the high voltage is a second voltage that is greater than the first voltage.

4. The integrated circuit device according to claim 1, wherein the nonvolatile memory is electrically erasable and programmable read only memory (EEPROM).

5. The integrated circuit device according to claim 1, wherein the nonvolatile memory is FLASH memory.

6. The integrated circuit device according to claim 1, wherein the nonvolatile memory is a plurality of programmable fuse links.

7. The integrated circuit device according to claim 1, wherein the POR circuit monitors the power source voltage, and when below a certain minimum value causes a power-on-reset of the integrated circuit device.

8. The integrated circuit device according to claim 1, wherein the nonvolatile memory is programmed for the voltage regulator to be operative.

9. The integrated circuit device according to claim 1, wherein the nonvolatile memory is programmed for the voltage regulator to be in the bypass mode.

10. The integrated circuit device according to claim 1, wherein the voltage regulator is enabled when the integrated circuit device is in a high power mode.

11. The integrated circuit device according to claim 1, wherein the voltage regulator is disabled when the integrated circuit device is in a low power mode.

12. The integrated circuit device according to claim 1, wherein the integrated circuit device is a microcontroller.

13. The integrated circuit device according to claim 1, wherein the integrated circuit device is selected from any one of the group consisting of a microprocessor, digital signal processor, application specific integrated circuit (ASIC), and programmable logic array (PLA).

14. A method for controlling an internal voltage regulator of an integrated circuit device, said method comprising the steps of:
providing a voltage regulator in an integrated circuit device;
enabling the voltage regulator during initial start-up of the integrated circuit device;
supplying a regulated low voltage from the voltage regulator to nonvolatile memory and low voltage circuits of the integrated circuit device; and
reading the nonvolatile memory for determining whether to retain the voltage regulator enabled or to disable and bypass the voltage regulator.

15. The method according to claim 14, further comprising the step of enabling the voltage regulator during a power-on-reset of the integrated circuit device.
